(19) United States
(12) Patent Application Publication
(10) Pub. No.: US 2011/0109307 A1
(43) Pub. Date: May 12, 2011

(54) Digitally Operating Device for Detecting Metallically Conductive Parts

(76) Inventor: Manfred Artinger, Schonberg (DE)

(21) Appl. No.: 12/989,370

(22) PCT Filed: Apr. 22, 2009
(86) PCT No.: PCT/EP2009/002934

§ 371 Date: Jan. 10, 2011

(30) Foreign Application Priority Data
Apr. 23, 2008 (DE) 102008020360.2

(51) Int. Cl. G01R 33/12; H03M 1/12

(52) U.S. Cl. 324/239; 341/155

(57) ABSTRACT

A facility for generating a detection signal upon the presence of metallic-conducting parts in a conveyed flow that is at least largely nonconductive, in which an alternating electromagnetic field is established in a section of the conveyed flow to be monitored by means of an alternating current generator via a transmitter coil system, whereby a variation of the signal of said field that is triggered by passage of a part is detected by a receiver coil system and serves, in conjunction with a downstream digital-type analytical circuit, for derivation of a detection signal which then triggers an information and/or elimination of said part. The receiver coil system has an analog-to-digital converter assigned to it and the transmission of the received signal to the analytical circuit proceeds in digital form. An analog-to-digital conversion is also provided for the signal of the alternating current generator and the received signal, being available in digital form, and the signal of the alternating current generator, also being available in digital form, are supplied to the analytical circuit for derivation of the detection signal.

### FIELD OF THE INVENTION

The present invention relates to a facility for generating a detection signal upon the presence of metallic-conductive parts in a conveyed flow that is at least largely non-conductive.

### BACKGROUND INFORMATION

Facilities of this type usually work such that an alternating electromagnetic field is established in a section of the conveyed flow to be monitored by means of an alternating current generator via a transmitter coil system, whereby a variation of the signal of said field that is triggered by passage of a part is detected by a receiver coil system and serves, in conjunction with a downstream analytical circuit, for derivation of a detection signal which then triggers an information and/or elimination of said part. Facilities of this type are described in terms of their application and structure, for example, in German Patent Application Nos. 37 14 009 A1 and 40 17 780 A1 and the references mentioned therein. In this context, the detection signal serves for actuation of protective facilities, such as optical and/or acoustic signaling means, of shut-off facilities of the conveying facility or for deviation of a conveyed flow containing an interfering part into a collection vessel or the like. German Patent Application No. DE 195 21 266, referring to said facilities, describes that the analysis for obtaining the detection signal can proceed not only on an analog basis, but also on a digital basis. For this purpose, the output signal of the receiver coil system that is available in analog form is used to generate a phase signal and an amplitude signal, both of which are derived in analog form, and supplied to the analysis. External influences can cause difficulties in both the analog-type and the digital-type embodiment.

### SUMMARY

According to an example embodiment of the present invention, these difficulties may be overcome in a facility for generating a detection signal upon the presence of metallic-conducting parts in a conveyed flow that is at least largely non-conductive, in which an alternating electromagnetic field is established in a section of the conveyed flow to be monitored by means of an alternating current generator via a transmitter coil system, whereby a variation of the signal of said field that is triggered by passage of a part is detected by a receiver coil system and serves, in conjunction with a downstream digital-type analytical circuit, for derivation of a detection signal which then triggers an information and/or elimination of said part, in that the receiver coil system has an analog-to-digital converter assigned to it and the transmission of the received signal to the analytical circuit proceeds in digital form, in that an analog-to-digital conversion is also provided for the signal of the alternating current generator, and in that the received signal, being available in digital form, and the signal of the alternating current generator, also being available in digital form, are supplied to the analytical circuit for derivation of the detection signal.

According to a development of the present invention, the above described difficulties can also be overcome in a facility for generating a detection signal upon the presence of metallic-conducting parts in a conveyed flow that is at least largely non-conductive, in which an alternating electromagnetic field is established in a section of the conveyed flow to be monitored by means of a transmitter via a transmitter coil system, whereby a variation of the signal of said field that is triggered by passage of a part is detected by a receiver coil system and serves, in conjunction with a downstream digital-type analytical circuit, for derivation of a detection signal which then triggers an information and/or elimination of said part, in that the transmitter is provided as a digital transmitter whose digital output signal is supplied to the transmitter coil system by means of a digital-to-analog converter, in that the receiver coil system has an analog-to-digital converter assigned to it and the transmission of the received signal to the analytical circuit proceeds in digital form, and in that the received signal, being available in digital form, and the signal of the digital transmitter, being available in digital form, are supplied to the analytical circuit for derivation of the detection signal. An advantageous development is characterized in that the sampling rate of the analog-to-digital conversion is selected sufficiently high for at least a half-wave of the oscillation emitted by the alternating current generator can still be resolved. Moreover, it may be advantageous if an analog-type amplifier for the analog received signal is arranged upstream of the analog-to-digital converter. For this purpose, it may be advantageous to provide a 16-bit/analog-to-digital converter as analog-to-digital converter and for the amplifier to have an amplification factor of more than 50, preferably of approx. 100.

### BRIEF DESCRIPTION OF THE DRAWINGS

Example embodiments of the present invention are illustrated in more detail in the figures. The principle and basic set-up wiring diagram of a metal detection device of the type mentioned are illustrated by means of FIGS. 1 to 6. This presentation is described, e.g., in German Patent Application No. 195 21 266 C2. Subsequently, examples of embodiments according to the present invention are considered based on FIGS. 7 and 8.

FIG. 1 shows the view of a metal detection facility that surrounds a conveyor belt B.

FIG. 2 shows a section through a metal detection facility according to FIG. 1

FIG. 3 shows a wiring diagram including the transmitter coil and a coil system for reception that comprises two coils.

FIG. 4 shows a swing diagram for illustration of the effect of conductive parts in the conveyed goods flow on the signal detected by means of the coil system.

FIG. 5 shows the block diagram of a circuit for derivation of a detection signal.

FIG. 6 shows the time course of the signal that occurs upon the passage of a metallic-conductive part at the output of a threshold circuit that serves for emission of the detection signal.

FIG. 7 shows an arrangement according to the present invention including an analog-to-digital converter at the output of the receiver coil system and an analog-to-digital converter of the analog-type alternating current generator.

FIG. 8 shows a block diagram for a metal detection facility provided according to the present invention with a digital-type alternating current generator.

### DETAILED DESCRIPTION OF EXAMPLE EMBODIMENTS

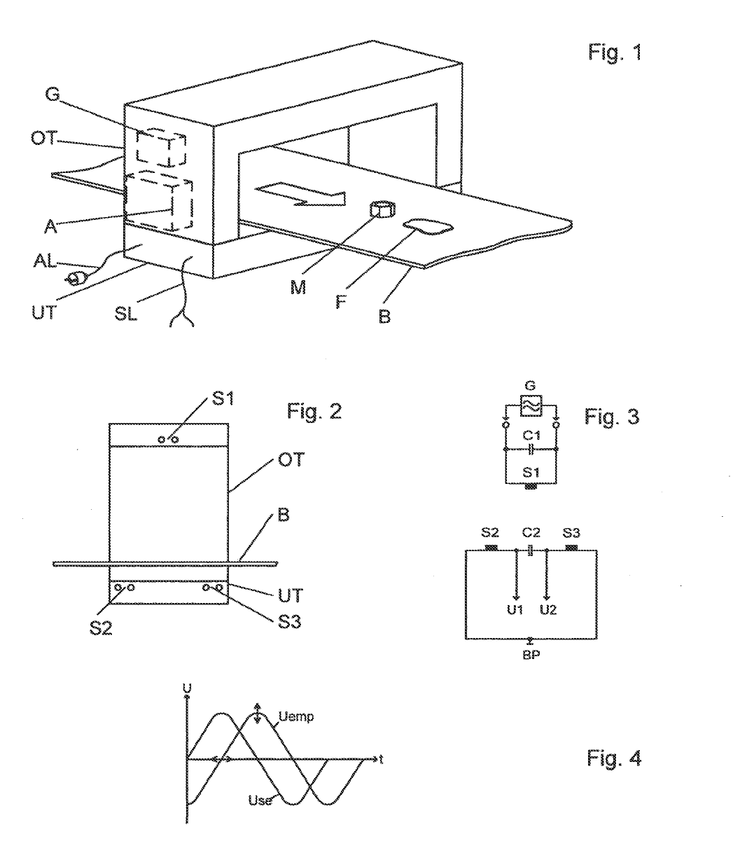

The facility shown schematically in FIGS. 1 and 2 consists of two components OT and UT, one of which is provided to be U-shaped and the other as a flat support. The two components surround a conveyor belt B that transports the goods to be checked for the presence of undesired metallic parts, such as a screw-nut M or a metal foil F, through the facility in the direction of the arrow shown. A transmitter coil S1 is arranged in said upper component OT. Moreover, a generator G supplying alternating current to the transmitter coil and a circuit A for derivation of a detection signal from metallic-conductive parts that are present in the conveyed goods are arranged in the part OT. Two receiver coils S2 and S3, staggered with respect to each other in the direction of conveying, are arranged in the support UT. The embodiment and arrangement of the coils as well as the shape of the housing and the shape and type of the through-opening are matched to the application on hand in generally conventional fashion. By means of contacts that are not shown in any detail here, their connections are guided to a circuit A in the component OT. A connection lead AL serves to connect the facility to the operating current supply. An output lead SL serves to conduct a detection signal ES triggered by a part to be detected to one of the protective devices mentioned above.

As shown in FIG. 3, it is customary to add a capacitor C2 each to the transmitter coil S1 and the pair of coils S2, S3, respectively, to complete an electrical resonant circuit. The two resonant circuits S1, C1 and S2, S3, C2 are matched such that they form a band filter matched to the frequency of the alternating current that is supplied by the generator G. Splitting the coil, and therefore the inductance in the oscillating circuit S2, S3, C2, allows for tapping of signals U1 and U2 that are 180° out of phase with respect to the reference potential BP and supplying them to the analytical circuit A.

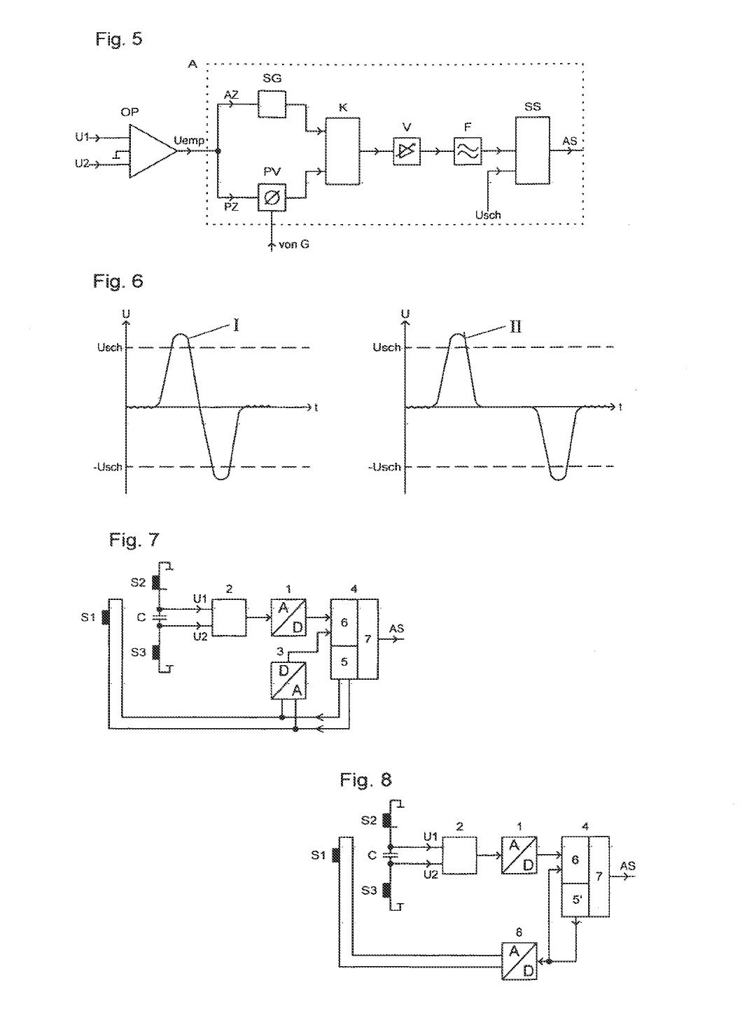

FIG. 4 illustrates the influence of passage of a metallic-conductive part that is moved past the coils S2 and S3 by the conveyor belt. The eddy currents caused by the alternating field of the coil vary both the amplitude and the phase angle of the signal Uemp that is received by means of 82 and S3, which, in the absence of such field variations is phase-shifted by 90° with respect to Use. The variations are indicated by arrows. The variation in amplitude and in phase is analyzed by means of AZ and PZ, respectively—as is evident from FIG. 5.

As shown in FIG. 5, circuit A begins with a difference amplifier OP that is formed by a so-called operational amplifier, serving as receiver, at the output of which a split into an amplitude branch AZ and a phase branch PZ is effected. In amplitude branch AZ, a rectifier module SG is used to determine the peak value of the signal Uemp. A phase discriminator PV, which is supplied with the signal Use of the generator G as phase reference signal, is incorporated in the phase branch PZ. The output voltages of SG and PV are supplied to a comparator K with variable weighting. In the simplest case, this is a subtractor featuring an amplitude controller in at least one of its two inputs.

The output signal of the comparator K is supplied via a filter

F, possibly after amplification in an amplifier V, to a threshold circuit SS at the output of which the detection signal AS of a metallic-conductive part to be classified as a disturbance can be tapped. For this purpose, a variable reference voltage Usch is supplied to the threshold circuit SS such that the detection signal AS is present at the output of SS if said reference voltage is exceeded. The filter F suppresses the direct voltage portion in the output of K and limits the frequency spectrum to the range intended for the analysis. During the transport of a metallic-conductive part through the facility described above according to FIGS. 1 to 4, a signal is present at the input of V and/or SS that shows an amplitude profile that is characteristic of the moved part. If the part is short with respect to the distance between the coils S2 and 53, each passage of one of the coils leads to the generation of a signal like the one denoted I in FIG. 6. In contrast, if the part is long by comparison, the profile of AS is approximately as indicated by II.

The section of the circuit from the output of OP to the output of SS basically forms the analytical circuit. As shown in FIG. 5, the analytical circuit begins downstream from the difference amplifier OP that is formed by a so-called operational amplifier and serves as receiver, at the output of which difference amplifier OP a split into an amplitude branch AZ and a phase branch PZ is effected. In amplitude branch AZ, a module SG is used to determine the absolute value of the signal Uemp which represents the amplitude variation signal AS. A phase discriminator PV which is supplied with the signal Use of the generator G as phase reference signal is incorporated in the phase branch PZ. The phase variation signal PS is applied to the output of PV.

The influence of the passage of a metallic-conductive part that is moved past the coil S2 by the conveyor belt is shown schematically in FIG. 6. The eddy currents caused in the part by the alternating field Use of the coil S1 vary both the amplitude and the phase angle of the signal Uemp that is received by means of S2 and S3, which would be 90° out of phase with respect to Use in the absence of said field variation. The ranges of variation are indicated by arrows. FIG. 6 shows the effect of the reference voltage Usch in the threshold circuit SS. An output signal AS that serves as the detection signal is present only if the threshold values are exceeded. Threshold circuits of this type are generally conventional. The threshold circuit also effectively suppresses the influence of background noise, which is indicated in FIG. 6 to precede and following the actual signals.

In the exemplary embodiment of the present invention shown in FIG. 7, an analog-to-digital converter 1, which preferably has an analog-type amplifier 2 arranged upstream of it, is connected to the output of the receiver coil system. The signals U1, U2 received by the receiver coil system S2, S3 are transmitted as one signal in digital form to the comparator 6 of an analytical unit 4. A transmission signal portion is tapped at the alternating current generator 5 that supplies the transmitter coil and supplied to an analog-to-digital converter 3. The digital output signal thereof is supplied as second input signal to a digital-type comparator 6 of the analytical unit 4 to form a detection signal. Preferably, the converters 1, 3 are provided such as to emit unipolar output signals. The digital signal on the output of the comparator 6 (compare K in FIG. 5) is then processed by digital-type components, such as a filter 7 etc., to generate the detection signal AS.

The analog-to-digital converter 1 is arranged as closely as possible to the receiver coil system S2, S3. Disturbing signal interference is prevented by this means. The digital transmission path from the output of the converter 1 to the input of the analytical unit 4 is much less sensitive to those.

The sampling rate of analog-to-digital conversion, i.e., the sampling rate for the sampling of amplitude samples from the analog signal, is selected sufficiently high such that, according to the conventional sampling theorem, at least one half-wave of the oscillation emitted by the alternating current generator is still resolved. A sampling rate of approx. 1 megahertz is recommended to ensure universal applicability in various applications, because there is a mutual correlation between the sampling rate and the amplification factor. It has proven to be advantageous to provide a 16-bit/analog-to-digital converter as analog-to-digital converter and the amplifier to feature an amplification factor of more than 50, preferably 100.

The block diagram of FIG. 8 shows another advantageous embodiment including the wiring of the individual components. The reference signs are used like in FIG. 7.

A cable leads from the receiver coil system S1, S2 to the analog-to-digital converter 1 that is implemented as a high-resolution analog-to-digital converter. An alternating current generator 5′ that is not shown in detail is provided in the analytical unit 4, which is provided with the comparator 6, and emits its signal in the from of a digital signal, unlike in the embodiment according to FIG. 7. Generators of this type are described, for example, in Horst Geschwinde “Einführung in die PLL-Technik”, Vieweg-Verlag, 1978. Said transmission signal is supplied to the transmitter coil S1 as an analog signal by means of a digital-to-analog converter 8. In order to reduce background noise portions, a filter 7 is provided as a digital module in this embodiment as well.

The data connection for signal exchange between the individual system components is effected by means of a bus system in the exemplary embodiments, in particular on the basis of the conventional Ethernet system. For this purpose, it is customary to assign so-called “controllers”, i.e., control modules with storage capability, to the individual system components. By this means, it is possible to have a central control unit comprising a control field convey the individual components to the requisite operational state such that they keep working by themselves without the central control once they are set by the central control.

The following comments shall be added with regard to the correlation between signal amplification before analog-to-digital conversion and the resolution of the analog-to-digital converter. Pre-amplification of the analog receiver coil signal before generating the phase and amplitude signals requires a high degree of amplification, for example approx. 10⁵ and more. Then, a signal resolution of approx. 4.9 millivolt is attainable, for example with a 10-bit analog-to-digital converter. In an embodiment according to the present invention, i.e., conversion of the receiver coil signal to a digital signal followed by generation of phase signal and amplitude signal in the digital part of the overall circuit, the use of a 16-bit analog-to-digital converter and pre-amplification of the receiver coil signal by 10² allows a signal resolution of approx. 38 microvolt to be attained.

For reasons of clarity, the control unit and the associated display unit for the operational status are not shown in the figure. These units are usually arranged at a different location, away from the actual metal detector for ergonomic reasons. In a preferred embodiment of the present invention, the analog-to-digital conversion is provided a short distance of less than a few decimeters from the receiver coils. The actual analytical circuit can then either be provided at a larger distance therefrom or made to join the analog-to-digital converter on a circuit board. In the latter case, said circuit module can then be accommodated in a sealable recess in the coil housing like in a facility described in, for example, German Patent Application No. DE 195 21 266.

### OVERVIEW OF REFERENCE NUMBERS AND CHARACTERS

A->Analog-type analytical circuit
AL->Power supply connection cable
AZ->Amplitude branch
B->Conveyor belt
BP->Reference potential
C1, C2->Capacitors
ES->Detection signal of an interfering part
F->Metal foil
G->Alternating current generator
K->Comparator
M->Screw-nut
OP->Difference amplifier and/or operational amplifier
OT->Upper component of a facility for the detection of parts
PV->Phase discriminator
PZ->Phase branch
S1->Transmitter coil for generation of a field
S2, S3->Receiver coils for the electromagnetic field
SG->Rectifier module in amplitude branch AZ
SS->Detection signal module
U1, U2->Signals tapped at coils S2 and S3, respectively
Uemp->Signal received at the output of difference amplifier OP
Use->Signal of generator G
UT->Lower component of a facility for the detection of parts
1->Analog-to-digital converter
2->Analog amplifier
3->Digital-to-analog converter
4->Analytical unit
5->Alternating current generator (analog)
5′->Alternating current generator (digital)
6->Comparator
7->Filter
8->Digital-to-analog converter

1-5. (canceled)

6. A system for generating a detection signal upon the presence of metallic conducting parts in a conveyed flow that is at least largely non-conductive, comprising:
an alternating current generator to establish an alternating electromagnetic field in a section of the conveyed flow to be monitored via a transmitter coil system;
a receiver coil system to detect a variation of a signal of the field that is triggered by passage of a part;
a downstream digital-type analytical circuit that receives a signal from the receiver coil system and derives a detection signal which triggers at least one of an information and elimination of said part; and
an analog-to-digital converter assigned to the receiver coil system, transmission of the signal from the receiver coil system to the analytical circuit proceeding in digital form, whereby an analog-to-digital conversion is also provided for a signal of the alternating current generator, which is arranged in the analytical circuit, and whereby the signal from the receiver coil system in digital form, and the signal of the alternating current generator in digital form being supplied directly to the analytical circuit for derivation of the detection signal.

7. A system for generating a detection signal upon the presence of metallic conducting parts in a conveyed flow that is at least largely non-conductive, comprising:
a transmitter to establish an alternating electromagnetic field in a section of the conveyed flow to be monitored via a transmitter coil system;
a receiver coil system to detect a variation of a signal of the field that is triggered by passage of a part; and
a downstream digital-type analytical circuit to receive a signal from the receiver coil system and derives a detection signal which then triggers at least one of an information and elimination of said part;
wherein the transmitter is a digital transmitter whose digital output signal is supplied to the transmitter coil system by means of a digital-to-analog converter, the receiver coil system has an analog-to-digital converter assigned to it and the transmission of the signal from the receiver coil system to the analytical circuit proceeds in digital form, and the analog-to-digital converter supplies the signal from the receiver coil system in digital form, and the signal of the digital transmitter in digital form directly to the analytical circuit for derivation of the detection signal.

8. The system according to claim 6, wherein the analog-to-digital conversion has a sampling rate that is sufficiently high for at least a half-wave of an alternating current signal producing the alternating field to still be resolvable in the coils of the receiver coil system.

9. The system according to claim 7, wherein the analog-to-digital conversion has a sampling rate that is sufficiently high for at least a half-wave of an alternating current signal producing the alternating field to still be resolvable in the coils of the receiver coil system.

10. The system according to claim 6, further comprising:
an analog-type amplifier for an analog signal from the receiver coil system is arranged upstream of the analog-to-digital converter.

11. The system according to claim 10, wherein the analog-to-digital converter associated with the receiver coil system is a 16-bit/analog-to-digital converter, and the amplifier has an amplification factor of more than 50.

12. The system according to claim 11, wherein the amplification factor is 100.
